(19) United States
(12) Patent Application Publication
(10) Pub. No.: US 2011/0042707 A1
(43) Pub. Date: Feb. 24, 2011

(54) Substrate for flexible display device, OLED display device including the same, and associated methods

(76) Inventors: Jin-O Lim, Yongin-City (KR); Sung-Guk An, Yongin-City (KR); Kie Hyun Nam, Yongin-City (KR)

Correspondence Address: LEE & MORSE, P.C., 3141 FAIRVIEW PARK DRIVE, SUITE 500, FALLS CHURCH, VA, 22042, US

(21) Appl. No.: 12/805,727

(22) Filed: Aug. 17, 2010

(30) Foreign Application Priority Data
Aug. 20, 2009 (KR) 10-2009-0077257

(51) Int. Cl. H01L 51/52; C09K 19/52; B29D 11/00; B32B 27/06; B32B 27/36; B32B 27/28

(52) U.S. Cl. 257/99; 252/194; 264/1.7; 428/446; 428/702; 428/698; 428/480; 428/412; 428/473.5; 428/704; 428/532; 428/521; 428/421; 257/E51.018

(57) ABSTRACT

A substrate for a flexible display device, an OLED display device including the same, and associated methods, the substrate including a composite of an inorganic layered compound and a moisture-absorption material, and a polymer resin.

### BACKGROUND

1. Field

Embodiments relate to a substrate for a flexible display device, an organic light emitting diode (OLED) display device including the same, and associated methods.

2. Description of the Related Art

An organic light emitting diode (OLED) display device, a kind of flat panel display device, may include a base substrate with an OLED disposed thereon. The OLED display device may also include an encapsulation substrate for protecting the OLED from deterioration.

The base substrate and the encapsulation substrate (hereinafter, referred to as ‘substrates’), may include glass substrates. However, glass substrates may be heavy and may be damaged by external impact. Therefore, glass substrates may not be suitable for portable devices having a large-scale screen. Also, because glass substrates may be damaged by external impact, a glass substrate should not be used for a flexible display device

Recently, a flat panel display device using a plastic substrate has been developed that is not only light in weight and strong against impact, but also flexible.

A flexible plastic substrate may have various advantages, e.g., portability, safety, and light weight, compared to a glass substrate. Also, because the plastic substrate may be manufactured through, e.g., a deposition or printing process, production costs may be reduced. Furthermore, unlike a conventional sheet-based process, because the plastic substrate may be used to manufacture a display device through a roll-to-roll process, it may be possible to manufacture a display device at a low production cost through mass production.

### SUMMARY

Embodiments are directed to a substrate for a flexible display device, an organic light emitting diode (OLED) display device including the same, and associated methods, which substantially overcome one or more of the problems due to the limitations and disadvantages of the related art.

It is a feature of an embodiment to provide a flexible display device that simplifies a manufacturing process and prevent permeation of moisture.

At least one of the above and other features and advantages may be realized by providing a substrate for a flexible display device including a composite of an inorganic layered compound and a moisture-absorption material, and a polymer resin.

The composite and the polymer resin may be mixed with each other.

The moisture-absorption material may be included in an amount of about 0.001 to about 50 parts by weight, based on 100 parts by weight of the inorganic layered compound.

The inorganic layered compound may be included in an amount of about 0.01 to about 30 parts by weight, based on 100 parts by weight of the polymer resin.

The substrate may include a polymer resin layer, the polymer resin layer including the polymer resin, and a composite layer, the composite layer including the composite and being disposed on the polymer resin layer.

The inorganic layered compound may include at least one of montmorillonite, kaolinite, nacrite, magadiite, kenyaite, hectorite, vermiculite, smectite, dickite, halloysite, antigorite, chrysotile, pyrophyllite, tetrasilylic mica, sodium taeniolite, talc, and mica.

The moisture-absorption material may include at least one of calcium oxide, magnesium oxide, barium oxide, aluminum nitride, boron nitride, silica, alumina, and zeolite.

The polymer resin may include at least one of polyimide, polyacrylate, polyethylene terephthalate, polyethylenenaphthalate, polycarbonate, polyarylate, polyetherimide, polyethersulfone, triacetic acid cellulose, polyvinylidene chloride, polyvinylidene fluoride, and an ethylene-vinylalcohol copolymer.

Surfaces of the inorganic layered compound may be coated by the moisture-absorption material.

At least one of the above and other features and advantages may also be realized by providing a method for manufacturing a substrate for a flexible display device including forming a flexible substrate including a composite of an inorganic layered compound and a moisture-absorption material, and a polymer resin.

Forming the flexible substrate may include forming the composite, forming the composite including mixing the inorganic layered compound with the moisture-absorption material, preparing a composite solution, preparing the composite solution including mixing the composite with a polymer resin solution, and performing a heat treatment on the composite solution.

The heat treatment may be performed at a temperature of about 25 to about 600° C.

The moisture-absorption material may be included in an amount of about 0.001 to about 50 parts by weight based on 100 parts by weight of the inorganic layered compound.

The inorganic layered compound may be included in an amount of about 0.01 to about 30 parts by weight, based on 100 parts by weight of the polymer resin.

Forming the flexible substrate may include forming a polymer resin layer, the polymer resin layer including the polymer resin, and forming a composite layer on the polymer resin layer, the composite layer including the composite.

Surfaces of the inorganic layered compound may be coated by the moisture-absorbing material.

At least one of the above and other features and advantages may also be realized by providing an organic light emitting diode display including a first substrate, an organic light emitting diode on the first substrate, the organic light emitting diode including an anode, a cathode, and an organic emission layer interposed between the anode and cathode, and a second substrate encapsulating the organic light emitting diode, wherein at least one of the first substrate and the second substrate includes a composite of an inorganic layered compound and a moisture-absorption material, and a polymer resin.

The composite and the polymer resin may be mixed with each other.

At least one of the first and second substrates may include a polymer resin layer, the polymer layer including the polymer resin, and a composite layer, the composite layer including the composite and being disposed on the polymer resin layer.

Surfaces of the inorganic layered compound may be coated by the moisture-absorption material.

### BRIEF DESCRIPTION OF THE DRAWINGS

The above and other features and advantages will become more apparent to those of ordinary skill in the art by describing in detail exemplary embodiments with reference to the attached drawings, in which:

FIG. 1 illustrates a cross-sectional view of an organic light emitting diode

(OLED) display device according to an embodiment;

FIG. 2 illustrates a schematic diagram of a composite of an inorganic layered compound and a moisture-absorption material according to an embodiment;

FIG. 3 illustrates a cross-sectional view of a base substrate for a flexible display device according to an embodiment;

FIG. 4 illustrates a cross-sectional view of a base substrate for a flexible display device according to another embodiment;

FIG. 5 illustrates a cross-sectional view of an encapsulation substrate for a flexible display device according to an embodiment; and

FIG. 6 illustrates a cross-sectional view of an encapsulation substrate for a flexible display device according to another embodiment.

### DETAILED DESCRIPTION

Korean Patent Application No. 10-2009-0077257, filed in the Korean Intellectual Property Office on Aug. 20, 2009, and entitled: “Substrate for Flexible Display Device, Method of Manufacturing the Same and OLED Display Device Including the Substrate,” is incorporated by reference herein in its entirety.

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

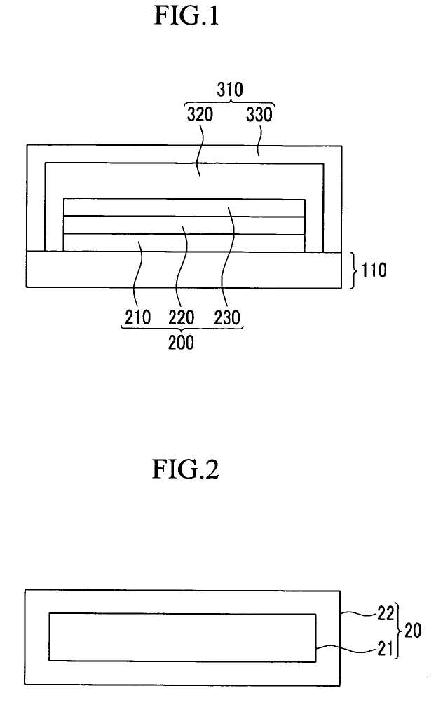

Referring to FIG. 1, an organic light emitting diode (OLED) display device will be described in accordance with an embodiment. FIG. 1 illustrates a cross-sectional view of an OLED display device according to an embodiment.

The OLED display device according to an embodiment may include an organic light emitting diode 200, a base substrate 110 supporting the organic light emitting diode 200, and an encapsulation member 310 encapsulating the organic light emitting diode 200. The organic light emitting diode 200 may include a lower electrode 210, an organic emission layer 220, and an upper electrode 230.

Any one of the lower electrode 210 and the upper electrode 230 may be an anode and the other may be a cathode. The anode may be an electrode in which holes are generated. The anode may be formed of a transparent conductive material with a high work function and high light transmittance. The transparent conductive material of the anode may include, e.g., ITO and/or IZO. The cathode may be an electrode in which electrons are generated. The cathode may be formed of a conductive material that has a low work function and is compatible with an organic material in the organic emission layer 220. The conductive material of the cathode may include, e.g., aluminum (Al), calcium (Ca), and/or barium (Ba).

The organic emission layer 220 may include, e.g., an organic material that emits light when voltage is applied to the lower electrode 210 and the upper electrode 230.

At least one auxiliary layer (not shown) may be further disposed between the lower electrode 210 and the organic emission layer 220 and/or between the upper electrode 230 and the organic emission layer 220. The auxiliary layer may include, e.g., a hole transporting layer (HTL), a hole injecting layer (HIL), an electron injecting layer (EIL), and/or an electron transporting layer (ETL), to provide a balance between electrons and holes.

The base substrate 110 may be disposed below the organic light emitting diode 200 and may support the organic light emitting diode 200. The base substrate 110 may be a flexible substrate and may include, e.g., a polymer resin and a composite of an inorganic layered compound and a moisture-absorption material.

The composite of the inorganic layered compound and the moisture-absorption material may be prepared by mixing the inorganic layered compound and the moisture-absorption material.

The inorganic layered compound may have a layered structure, e.g., wherein plate-shaped unit crystals are stacked. The inorganic layered compound may include, e.g., a montmorillonite, kaolinite, nacrite, magadiite, kenyaite, hectorite, vermiculite, smectite, dickite, halloysite, antigorite, chrysotile, pyrophyllite, tetrasilylic mica, sodium taeniolite, talc, and/or mica. The inorganic layered compound may absorb solvent and expand.

The moisture-absorption material may be any suitable material that absorbs moisture, and is not limited to specific materials. In an implementation, the moisture-absorption material may include, e.g., calcium oxide, magnesium oxide, barium oxide, aluminum nitride, boron nitride, silica, alumina, and/or zeolite.

FIG. 2 illustrates a schematic diagram of a composite of an inorganic layered compound and a moisture-absorption material. Referring to FIG. 2, the composite 20 may have a structure in which surfaces of the plate-shaped inorganic layered compound 21 are surrounded (coated) by the moisture-absorption material 22. The composite 20 may be, e.g., plate-shaped particles having a length of about 50 nm to about 500 nm. The composite 20 may be prepared in the form of solution.

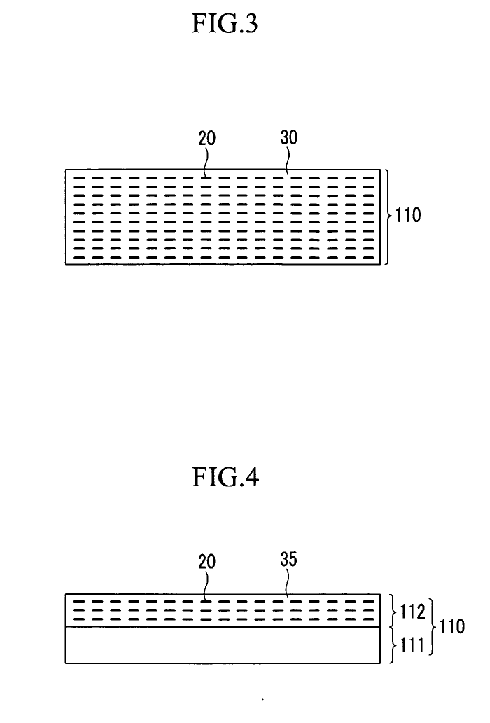

FIG. 3 illustrates a cross-sectional view of a base substrate for a flexible display device according to an embodiment. Referring to FIG. 3, the above-described composite 20 may be mixed with a polymer resin 30 to thereby prepare the base substrate 110.

The base substrate 110 of FIG. 3 may be prepared as follows. The composite 20 may be formed by mixing the aforementioned inorganic layered compound 21 with the moisture-absorption material 22. The moisture-absorption material 22 may be included in an amount of about 0.001 to about 50 parts by weight, based on 100 parts by weight of the inorganic layered compound 21. Maintaining the amount of the moisture-absorption material at about 0.001 to about 50 parts by weight may help ensure that moisture and oxygen are efficiently prevented from entering the display device.

The inorganic layered compound 21 may be included in an amount of about 0.01 to about 30 parts by weight, based on 100 parts by weight of the polymer resin 30. Maintaining the amount of the inorganic layered compound at about 0.01 to about 30 parts by weight may help ensure that moisture and oxygen are efficiently prevented from entering the display device.

Then, a composite solution may be prepared by mixing the composite 20 with a polymer resin solution. The polymer resin solution is not limited to a specific material and any suitable material that may be used as a plastic substrate may be used for the polymer resin solution. In an implementation, the polymer resin solution may include, e.g., polyimide, polyacrylate, polyethylene terephthalate, polyethylenenaphthalate, polycarbonate, polyarylate, polyetherimide, polyethersulfone, triacetic acid cellulose, polyvinylidene chloride, polyvinylidene fluoride, and/or an ethylene-vinylalcohol copolymer. If necessary, a sonicator may be used to uniformly disperse the composite 20 in the polymer resin solution, i.e., to remove lumps.

Then, the base substrate 110 having a predetermined thickness may be manufactured by performing a heat treatment on the composite solution and molding the heat treated composite solution. The heat treatment may be performed at about 25 to about 600° C.

FIG. 4 illustrates a cross-sectional view of a base substrate 110 for a flexible display device according to another embodiment. In contrast to the above-described base substrate, the base substrate 110 according to the present embodiment may include a composite layer 112 including the above-described composite 20, the composite layer 112 being disposed on a polymer resin layer 111 made of a polymer resin.

The polymer resin layer 111 may include, e.g., polyimide, polyacrylate, polyethylene terephthalate, polyethylene naphthalate, polycarbonate, polyarylate, polyetherimide, polyethersulfone, triacetic acid cellulose, polyvinylidene chloride, polyvinylidene fluoride, and/or an ethylene-vinylalcohol copolymer.

The composite layer 112 may be formed by applying a composite solution to the polymer resin layer 111. The composite solution may be prepared by mixing the inorganic layered compound 21 with the moisture-absorption material 22 to thereby prepare the composite 20 and then mixing the composite 20 with a solvent 35. The solvent 35 is not limited to a specific solvent. In an implementation, the solvent 35 may include, e.g., water, alcohol, dimethyl formamide, dichloromethane, chloroform, toluene, and/or acetone.

The polymer resin layer 111 and the composite layer 112 may each have a thickness of, e.g., about 0.1 to about 300 μm.

The base substrate 110 may be, e.g., a plastic substrate, and, because it is light in weight and flexible, may have excellent portability and may be resistant to external impact. Also, as described above, since the base substrate 110 may be formed of a liquid-phase material, it may be formed in a desirable size. Thus, the base substrate 110 may be applied to a large-scale display device. Furthermore, the base substrate 110 may have a structure in which a composite of an inorganic layered compound and a moisture-absorption material is uniformly dispersed in a polymer resin. The inorganic layered compound may effectively remove moisture entering from the exterior by the moisture-absorption material while having a light transmittance of about 80% or greater.

The encapsulation member 310 (FIG. 1) may include a filler 320 and an encapsulation substrate 330. The filler 320 may be, e.g., an inorganic filler or an organic filler. The encapsulation substrate 330 may encapsulate the organic light emitting diode 200, and may prevent moisture and oxygen from entering the device.

Just as the base substrate 110 described above, the encapsulation substrate 330 may be a flexible substrate and may include the polymer resin and the composite 20 of the inorganic layered compound 21 and the moisture-absorption material 22.

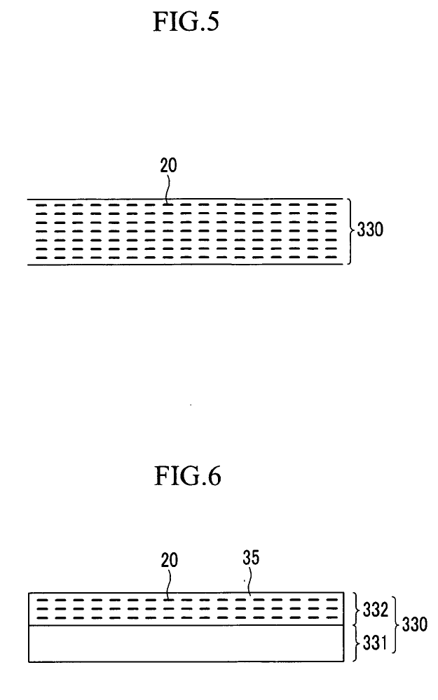

FIG. 5 illustrates a cross-sectional view of an encapsulation substrate for a flexible display device according to an embodiment. Referring to FIG. 5, the encapsulation substrate 330 may be manufactured by mixing the composite 20 with the polymer resin 30. This will be described in detail below.

FIG. 6 illustrates a cross-sectional view of an encapsulation substrate for a flexible display device according to another embodiment. Referring to FIG. 6, the encapsulation substrate 330 may include a polymer resin layer 331 and a composite layer 332. The polymer resin layer 331 may be made of a polymer resin and the composite layer 332 may be formed on the polymer resin layer 331 and may include the composite 20.

Since the inorganic layered compound, the moisture-absorption material, and the manufacturing method may be the same as described in the above, repeated description thereof is omitted.

An embodiment may provide a flexible OLED display device using the above-described plastic substrate as both the base substrate 110 and the encapsulation substrate 330. Also, since the inorganic layered compound may have a high light transmittance, it may be effectively applied to both a bottom emission structure in which the OLED emits light toward the base substrate 110 and a top emission structure in which the OLED emits light toward the encapsulation substrate 330. Moreover, since moisture entering from the exterior may be effectively removed by the moisture-absorption material, it is possible to prevent the organic light emitting diode 200 from being deteriorated by the moisture.

In particular, using the above-described flexible substrate as the encapsulation substrate 330 may prevent the organic light emitting diode from being affected by, e.g., a parasitic capacitance due to electric conductivity of metal, which may otherwise occur if metal foil is used as an encapsulation substrate, and from being easily corroded by oxygen.

As described above, both the base substrate 110 and the encapsulation substrate 330 may include a polymer resin and a composite of an inorganic layered compound and a moisture-absorption material. However, the embodiments are not limited thereto and either the base substrate 110 or the encapsulation substrate 330 may include the polymer resin and the composite of an embodiment.

Hereinafter, the above described embodiments are described in more detail with reference to the following Examples.

### Examples 1-4

Montmorillonite (MMT) and calcium oxide (CaO) were mixed in ratios presented in Table 1 to prepare respective composites. A composite solution was prepared by mixing the composite with polyamic acid solution as a polymer resin. Then, aggregated composite lumps were pulverized for about 24 hours by applying ultrasonic waves thereto with a sonicator. A glass substrate (as a support) was coated with the composite solution. Then, the coated glass substrate underwent a heat treatment at about 350° C. to manufacture a flexible substrate on the glass substrate, the flexible substrate including polyimide-montmorillonite-calcium oxide.

TABLE 1

| | MMT | CaO |
|---|---|---|
| | x | y |
| Example 1 | 0.5 | 30 |
| Example 2 | 1 | 30 |
| Example 3 | 0.5 | 50 |
| Example 4 | 1 | 50 |

x: parts by weight of MMT based on 100 parts by weight of polyimide
y: parts by weight of CaO based on 100 parts by weight of MMT

### Comparative Example 1

A substrate was manufactured by performing a heat treatment at about 350° C. on a glass substrate coated with a polyamic acid solution.

### Comparative Example 2

100 parts by weight of polyamic acid solution was mixed with 0.5 parts by weight of montmorillonite, coated on a glass substrate, and heat treated at about 350° C. to prepare a substrate including polyimide-montmorillonite.

### Comparative Example 3

100 parts by weight of polyamic acid solution was mixed with 1 part by weight of montmorillonite, coated on a glass substrate, and heat treated at about 350° C. to prepare a substrate including polyimide-montmorillonite.

Assessment

Moisture permeability was measured for the substrates manufactured according to Examples 1 to 4 and Comparative Examples 1 to 3. The moisture permeability was measured with a moisture permeability measurer produced by the MOCON company. The results are shown in Table 2.

TABLE 2

| | Moisture Permeability (g/m² day) |
|---|---|
| Example 1 | 0.7 |
| Example 2 | 0.08 |
| Example 3 | 0.5 |
| Example 4 | 0.06 |
| Comparative Example 1 | 8 |
| Comparative Example 2 | 5 |
| Comparative Example 3 | 1 |

It may be seen from Table 2 that the substrates according to Examples 1 to 4 exhibit lower moisture permeability than the substrates manufactured according to the Comparative Examples. This indicates that when a substrate according the Examples is used as both or any one of the base substrate and the encapsulation substrate, the amount of moisture entering from the exterior may be reduced, thereby protecting an OLED from deterioration.

In contrast, typical plastic substrates, e.g., Comparative Example 1, may require a separate blocking layer due to high moisture permeability of plastics. Forming the blocking layer may require an additional manufacturing step, thereby increasing a manufacturing time and cost.

Exemplary embodiments have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A substrate for a flexible display device, comprising:
a composite of an inorganic layered compound and a moisture-absorption material; and
a polymer resin.

2. The substrate for a flexible display device as claimed in claim 1, wherein the composite and the polymer resin are mixed with each other.

3. The substrate for a flexible display device as claimed in claim 2, wherein the moisture-absorption material is included in an amount of about 0.001 to about 50 parts by weight, based on 100 parts by weight of the inorganic layered compound.

4. The substrate for a flexible display device as claimed in claim 3, wherein the inorganic layered compound is included in an amount of about 0.01 to about 30 parts by weight, based on 100 parts by weight of the polymer resin.

5. The substrate for a flexible display device as claimed in claim 1, wherein the substrate comprises a polymer resin layer, the polymer resin layer comprising the polymer resin, and a composite layer, the composite layer comprising the composite and being disposed on the polymer resin layer.

6. The substrate for a flexible display device as claimed in claim 1, wherein the inorganic layered compound comprises at least one of montmorillonite, kaolinite, nacrite, magadiite, kenyaite, hectorite, vermiculite, smectite, dickite, halloysite, antigorite, chrysotile, pyrophyllite, tetrasilylic mica, sodium taeniolite, talc, and mica.

7. The substrate for a flexible display device as claimed in claim 1, wherein the moisture-absorption material comprises at least one of calcium oxide, magnesium oxide, barium oxide, aluminum nitride, boron nitride, silica, alumina, and zeolite.

8. The substrate for a flexible display device as claimed in claim 1, wherein the polymer resin includes at least one of polyimide, polyacrylate, polyethylene terephthalate, polyethylenenaphthalate, polycarbonate, polyarylate, polyetherimide, polyethersulfone, triacetic acid cellulose, polyvinylidene chloride, polyvinylidene fluoride, and an ethylene-vinylalcohol copolymer.

9. The substrate for a flexible display device as claimed in claim 1, wherein surfaces of the inorganic layered compound are coated by the moisture-absorption material.

10. A method for manufacturing a substrate for a flexible display device, comprising:
forming a flexible substrate including:
a composite of an inorganic layered compound and a moisture-absorption material, and
a polymer resin.

11. The method as claimed in claim 10, wherein forming the flexible substrate comprises:
forming the composite, forming the composite including mixing the inorganic layered compound with the moisture-absorption material;
preparing a composite solution, preparing the composite solution including mixing the composite with a polymer resin solution; and
performing a heat treatment on the composite solution.

12. The method as claimed in claim 11, wherein the heat treatment is performed at a temperature of about 25 to about 600° C.

13. The method as claimed in claim 11, wherein the moisture-absorption material is included in an amount of about 0.001 to about 50 parts by weight based on 100 parts by weight of the inorganic layered compound.

14. The method as claimed in claim 13, wherein the inorganic layered compound is included in an amount of about 0.01 to about 30 parts by weight, based on 100 parts by weight of the polymer resin.

15. The method as claimed in claim 10, wherein forming the flexible substrate comprises:
forming a polymer resin layer, the polymer resin layer including the polymer resin, and
forming a composite layer on the polymer resin layer, the composite layer including the composite.

16. The method as claimed in claim 10, wherein surfaces of the inorganic layered compound are coated by the moisture-absorbing material.

17. An organic light emitting diode display, comprising
a first substrate;
an organic light emitting diode on the first substrate, the organic light emitting diode including an anode, a cathode, and an organic emission layer interposed between the anode and cathode; and
a second substrate encapsulating the organic light emitting diode, wherein at least one of the first substrate and the second substrate includes:
a composite of an inorganic layered compound and a moisture-absorption material, and
a polymer resin.

18. The organic light emitting diode display as claimed in claim 17, wherein the composite and the polymer resin are mixed with each other.

19. The organic light emitting diode display as claimed in claim 17, wherein at least one of the first and second substrates comprises:
a polymer resin layer, the polymer layer including the polymer resin, and
a composite layer, the composite layer including the composite and being disposed on the polymer resin layer.

20. The organic light emitting diode display as claimed in claim 17, wherein surfaces of the inorganic layered compound are coated by the moisture-absorption material.
